(19) United States
(12) Patent Application Publication
(10) Pub. No.: US 2024/0055327 A1
(43) Pub. Date: Feb. 15, 2024

(54) PRE-PLATED LEAD TIP FOR WETTABLE FLANK LEADFRAME

(71) Applicant: TEXAS INSTRUMENTS INCORPORATED, Dallas, TX (US)

(72) Inventors: Makoto Yoshino, Beppu-Shi Oita-Ken (US); Hiroki Kawano, Hiji-machi Hayam-gun Oita-ken (JP); Hau Nguyen, San Jose, CA (US)

(73) Assignee: TEXAS INSTRUMENTS INCORPORATED, Dallas, TX (US)

(21) Appl. No.: 17/818,395

(22) Filed: Aug. 9, 2022

(51) Int. Cl. H01L 23/495; H01L 21/48

(52) U.S. Cl. CPC H01L 23/4951; H01L 23/49555; H01L 21/4842

(57) ABSTRACT

A method for making a semiconductor device is provided. The method generally includes forming a package having a first plurality of leads extending from a first side of the package, the package disposed on a leadframe. The method generally includes making a first cut adjacent to a first side of a first lead of the first plurality of leads, the first side extending from the first side of the package. The method generally includes making a second cut adjacent to a second side of the first lead of the first plurality of the lead, the second side of the lead opposite the first side of the lead and extending from the first side of the package.

### TECHNICAL FIELD

Examples of the present disclosure generally relate to semiconductor devices and, in particular, to leadframes in semiconductor devices.

### BACKGROUND

In some types of semiconductor packages, a semiconductor die is directly mounted to a leadframe via a plurality of interconnect bumps, or posts. The plurality of interconnect bumps electrically connects the semiconductor die to the leadframe. Each interconnect bump's contact surface at the semiconductor die is often the same size as the interconnect bump's contact surface area at the leadframe.

Some semiconductor packages require the leads of the leadframe to be plated. Specifically, some semiconductor packages require the package to be plated to the lead tip of the leaded packages because the leads are wettable flank leads. If the leads of these packages have no plating on the lead tip, problems can occur with automated optical inspection (AOI) inspection where solder wetness is not stable when mounted on the surface mount technology (SMT) board. Generally, the tips of the leads of the package are cut when the package is sectioned off from the leadframe, thus leaving no plating on the lead cutting surface, i.e., the lead tip. Accordingly, forming a stable solder fillet may not be possible during the SMT process.

### SUMMARY

This Summary is provided to comply with 37 C.F.R. § 1.73, requiring a summary of the invention briefly indicating the nature and substance of the invention. It is submitted with the understanding that it will not be used to interpret or limit the scope or meaning of the claims.

According to some examples, a method of forming a semiconductor package is described herein. The method generally includes forming the semiconductor package having a first plurality of leads extending from a first side of the semiconductor package, the semiconductor package disposed on a leadframe, the leadframe comprising the first plurality of leads, wherein each of the first plurality of leads comprises leadframe material and plating. The method generally includes making a first cut adjacent to a first side of a first lead of the first plurality of leads, the first side extending from the first side of the package. The method generally includes making a second cut adjacent to a second side of the first lead of the first plurality of the lead, the second side of the lead opposite the first side of the lead and extending from the first side of the semiconductor package.

According to some examples, a method for manufacturing a semiconductor device is described. The method generally includes forming a leadframe strip comprising a first package and a second package, the first package having a first plurality of leads extending from a first side of the first package towards the second package, the second package having a second plurality of leads extending from a second side of the second package toward the first package, the first package and the second package disposed adjacent to each other on the leadframe strip, wherein each of the first plurality of leads comprises leadframe material and plating. The method generally includes making a first cut adjacent to a first side of a first lead of the first plurality of leads, the first side extending from the first side of the first package toward the second package. The method generally includes making a second cut adjacent to a second side of the first lead of the first plurality of the lead, the second side of the lead opposite the first side of the lead and extending from the first side of the first package toward the second package.

According to some examples, a semiconductor device is described herein. The semiconductor device generally includes a first plurality of leads extending from a first side of a package, each of the first plurality of leads including a lead material and a plating on the lead material. The semiconductor device generally includes a first lead of the first plurality of leads having a first portion of the lead material exposed on a first end of a first side extending from the first side of the package. The first lead of the semiconductor device generally includes a second portion of the lead material exposed a first end of a second side extending from the first side of the package, the second side opposite the first side. The first lead of the semiconductor device generally includes full plating coverage on a third side, a fourth side, and a fifth side of the package, the third side between the first and second sides and extending from the first side of the package, the fourth side between the first and second sides and extending from the first side of the package, and the fifth side being adjacent to the first side, the second side, the third side, and the fourth side.

These and other aspects may be understood with reference to the following detailed description.

### BRIEF DESCRIPTION OF THE DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 is a flowchart illustrating operations for forming a semiconductor device, according to some examples.

FIG. 2A is a top view of a leadframe for a semiconductor device, according to some examples.

FIG. 2B illustrates cuts to a leadframe for a semiconductor device, according to some examples.

FIG. 3A is a top view of a leadframe for a semiconductor device, according to some examples.

FIG. 3B illustrates cuts to a leadframe for a semiconductor device, according to some examples.

FIGS. 4A-4D are top views of leadframes for semiconductor devices, according to some examples.

FIGS. 5A-5 D are top views of leadframes for semiconductor devices, according to some examples.

FIGS. 6A-6C are different views of a singulated semiconductor device, according to some examples.

FIGS. 7A-7C are different views of a singulated semiconductor device, according to some examples.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the description or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

Examples described herein presents multiple technically advantageous solutions to technical problems that arise with the manufacture of certain types of semiconductor packages. During the manufacturing of semiconductor packages, semiconductor packages are singulated from a leadframe strip, and during singulation of these semiconductor packages, the copper tips of the leads of the semiconductor packages are exposed, i.e., the lead tip is cut when the semiconductor package is sectioned off from the leadframe strip because there is no plating on the lead cutting surface.

Examples described herein provide semiconductor devices and method for manufacturing semiconductor devices with pre-plated lead tips. Pre-plated lead tips are advantageous for wettable flank lead packages, and wettable flanks leads are advantageous for making stable solder fillets when the semiconductor package is mounted on a surface mount technology (SMT) board. Without pre-plated lead tips, problems can occur during automated optical inspection (AOI) inspection where solder wetness is not stable when the semiconductor package is mounted on the SMT board. Examples described herein provide a leadframe design and methods for cutting up the leadframe strip without cutting the lead tips of the leadframes, ensuring pre-plated finishes (PPF) and/or solder plating at the lead tips.

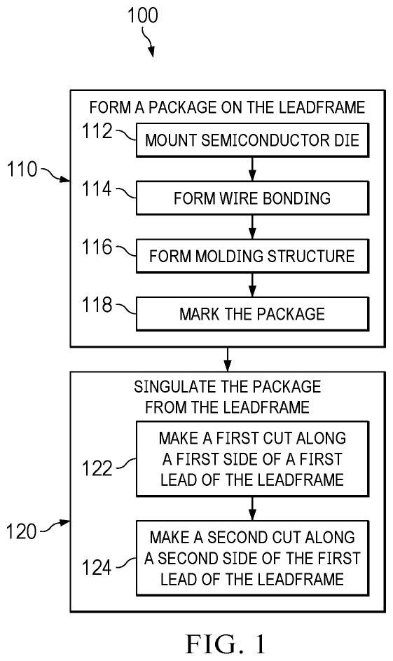

FIG. 1 is a flowchart illustrating operations for forming a semiconductor device, according to some examples.

Operations 100 begin, at step 110, with forming a semiconductor package having a first plurality of leads extending from a first side of the semiconductor package, the semiconductor package disposed on a leadframe. The leadframe of operations 100 includes the first plurality of leads and each of the first plurality of leads comprises leadframe material and plating.

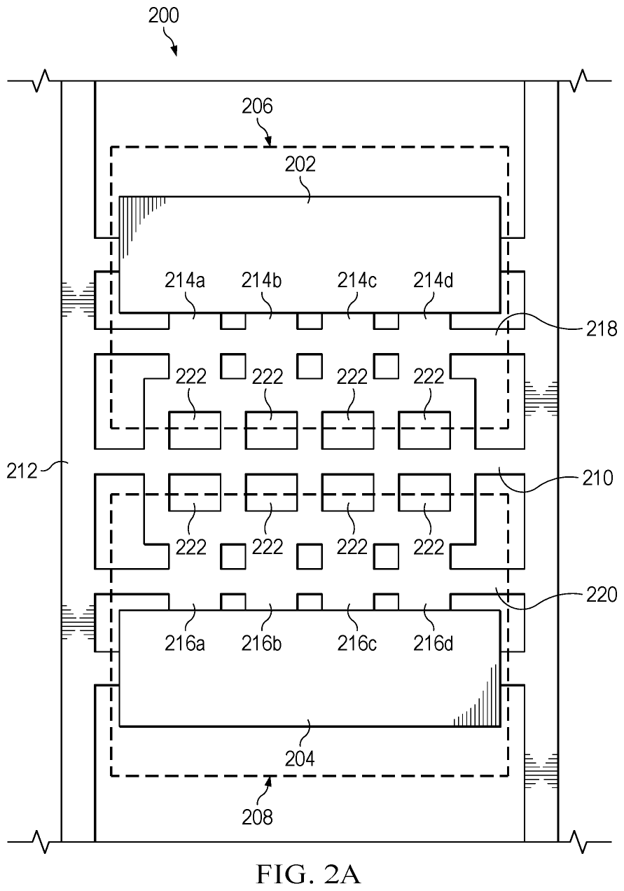

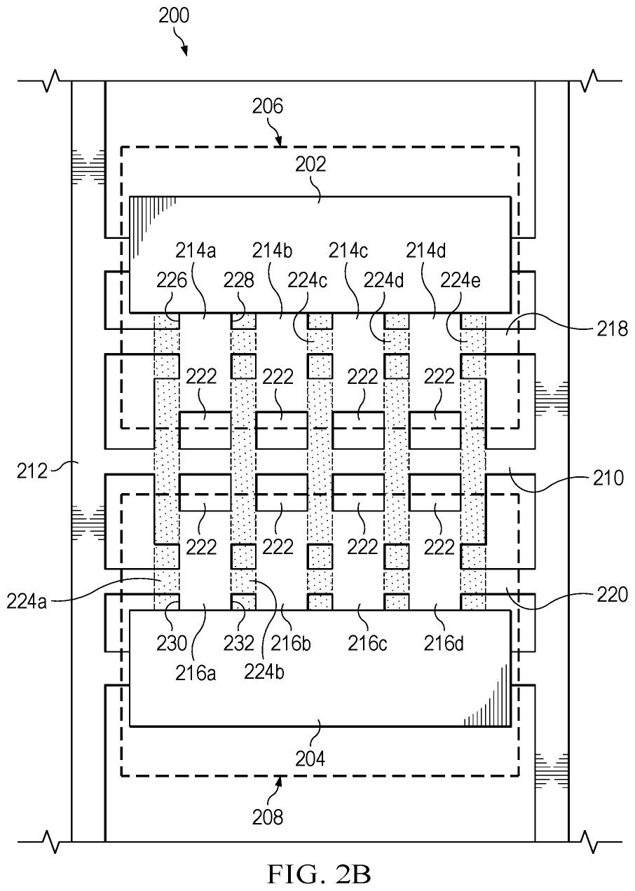

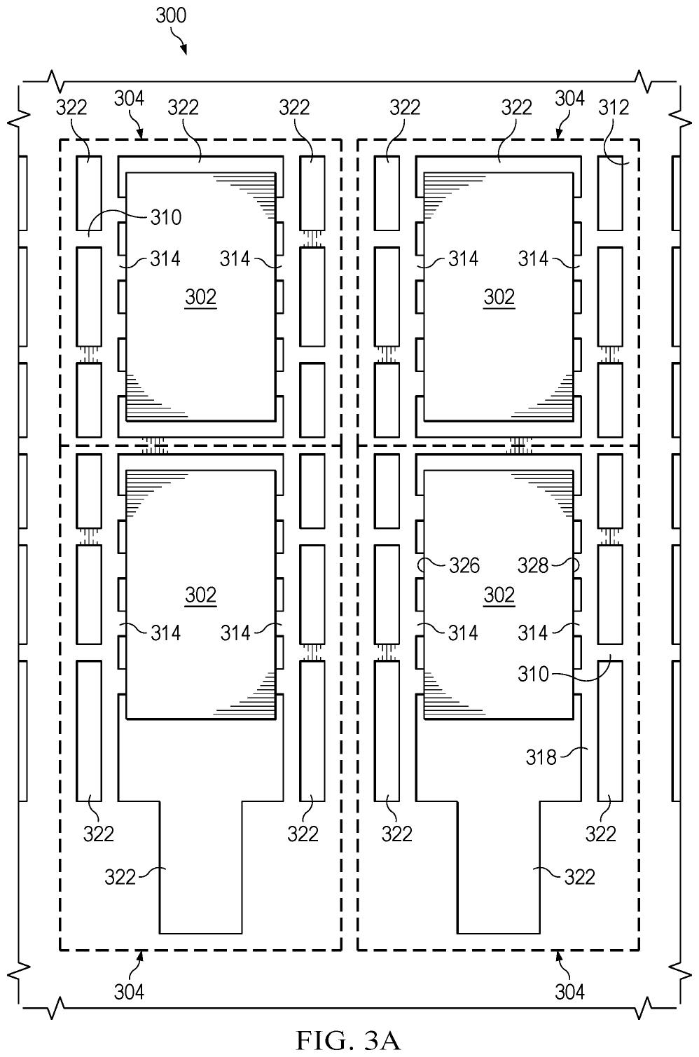

FIG. 2A is a top view of leadframes, according to some examples, with semiconductor packages 202, 204 formed on leadframes 206, 208 on a leadframe strip 200. “Leadframe” is a metal frame that provides external electrical connection to the packaged chip or semiconductor device, and “leadframe strip” means an alloy, e.g., copper alloy, or metal from which leadframe are formed. Any reference to either leadframe 206 or leadframe 208 can be applied to the leadframe and/or to any other leadframe described herein. As illustrated, leadframes 206, 208 are formed on a single, thin sheet of metal (i.e., the leadframe strip 200) as by stamping or etching, and multiple interconnected leadframes may be formed on a single leadframe strip 200. Any number of semiconductor packages can be formed on any number of leadframes of a leadframe strip. A leadframe strip can have any number of leadframes. Leadframes 206, 208 on the leadframe strip 200 can be arranged in rows and columns. Tie bars 210 connect leads and other elements of a leadframe to one another as well as to elements of adjacent leadframes in a leadframe strip. A siderail 212 may surround the array of leadframes to provide rigidity and support leadframe elements on the perimeter of the leadframe strip 200. The siderail 212 may also include alignment features to aid in manufacturing. The leadframe and the semiconductor package formed on the leadframe can depend on the semiconductor device being formed.

As illustrated, each leadframes 206, 208 of the leadframe strip 200 includes leads 214a, 214b, 214c, 214d of leadframe 206 (collectively leads 214) and leads 216a, 216b, 216c, 216d of leadframe 208 (collectively, leads 216). Any reference to a singular lead of the leads 214 or leads 216 can be applied to any of the leads 214 or leads 216. The leads 214, 216 of the leadframe 206, 208 are the lengthwise members extending from the semiconductor packages 202, 204. The semiconductor package 202, 204 each include a semiconductor die surrounded by a mold compound. A “semiconductor die” is the semiconductor chip with a function circuit or device. As illustrated, the leads 214, 216 extend from the sides of the semiconductor packages 202, 204 respectively and terminate at the tips of the leads 214, 216. Lead tips and tips of the leads may be used interchangeably, and refer to the ends of the leads 214, 216 located distally from where the leads 214, 216 start extending from their respective semiconductor packages 202, 204. In some examples, the leads 214, 216 can be coupled together by a dam bar 218, 220 respectively. The leadframes 206, 208 can also include perimeter contacts (not illustrated), interior vias (not illustrated), and die attach pad (not illustrated). In some examples, the leads 214, 216 of the leadframes 206, 208 are wettable flank leads. In some examples, the leads 214, 216 are designed as flat leads for flat lead packages, and in other examples, the leads 214, 216 are designed as gullwing leads for gullwing lead packages.

Each leadframe 206, 208 of the leadframe strip 200 includes openings 222 disposed adjacent to the tips of the leads 214, 216 of the leadframes 206, 208. “Opening” means a void or location where material has been removed or not formed. A reference to a singular opening can be applied to any of the openings 222. In some examples, the openings 222 can be made by a precision cut device. The tips of the leads 214, 216 are plated, and the openings 222 include the plated tips of the leads 214, 216. In some examples, tie bars 210 form some sides of the openings 222, such that the tie bars 210 and the tips of the leads 214, 216 form the sides of the openings 222. The openings 222 can have any size, and the perimeter of the openings 222 can include any number of tips of leads 214, 216. Accordingly, the tips of the leads 214, 216 can assist in defining the openings 222 and accordingly, the openings 222 ensure that the tips of the leads 214, 216 are still plated after singulation.

In some examples, the leadframes 206, 208 of the leadframe strip 200 can be formed from electroplated copper as a material. In addition to copper, other metals that can be electroplated can be used with the leadframes 206, 208 of the leadframe strip 200, including gold, silver, palladium, and alloys of these. As mentioned, examples described herein avoid exposing the leadframe material at the tips of the leads 214, 216 of the leadframes 206, 208, such that the tips of the leads 214, 216 are still plated. By maintaining the plating at the tips of the leads 214, 216, a stable solder fillet can be formed at the tips of the leads 214, 216 during an SMT process.

Forming the semiconductor package 202, 204 (step 110) can involve mounting a semiconductor die to a leadframe 206, 208 (step 112). In some examples, multiple semiconductor dies can be mounted on multiple leadframes 206, 208 of the leadframe strip 200, and any number of semiconductor dies can be mounted on a single leadframe. In some examples, multiple semiconductor dies can be mounted on the leadframe 206, 208 in a flipchip arrangement, with one semiconductor die mounted on one surface of the leadframe 206, 208 and another semiconductor die mounted on the opposite surface of the leadframe 206, 208. The semiconductor die can be directly mounted on the leadframe 206, 208. In some examples, the semiconductor die can be mounted to the leadframes 206, 208 via a plurality of interconnect bumps, pillars, posts, or any other connection type.

Forming the semiconductor package 202, 204 (step 110) can involve forming electrical connections (step 114), which electrically connects the semiconductor die to the leadframe 206, 208. In some examples, forming electrical connections can involve forming conductive wire bonds that connect the semiconductor die to leads of the leadframe 206, 208. In some examples, instead of wire bonding, semiconductor dies can be clipped or otherwise coupled to leads 214, 216 of the leadframe 206, 208. Electrical connections can also be formed between dies mounted on the leadframe 206, 208.

Forming the semiconductor package 202, 204 (step 110) involves forming the molding structure around the mounted semiconductor die and the wire bonds (step 116). When forming the molding structure, the die, portions of the leads 214, 216 of the leadframe 206, 208, and the connections between the semiconductor die and the leads 214, 216 are encapsulated using a molding material, such as epoxy, to protect the assembly from potentially damaging heat, physical trauma, moisture, and other deleterious factors. “Molding materials” are epoxy resins as part of semiconductor package 202, 204, and can include any materials to protect the assembly from the environment. The resins are at times filled with some sort of silica filler to reduce the coefficient of thermal expansion to better match that of the leadframe 206, 208 along with small amounts of other additives.

Forming the semiconductor package 202, 204 (step 110) involves marking the molded package (step 118). Marking the molded package can involve marking the molded package 202, 204 with information about the semiconductor package 202, 204 and the semiconductor die included therein. Marking the molded package 202, 204 can occur after the molded package 202, 204 is tested.

Operations 100 continue, at step 120, with singulating the semiconductor package 202, 204 from the leadframe 206, 208. Usually die mounting (step 112), die to lead attachment, such as wire bonding (step 114), and molding (step 116) to cover at least part of the leadframe 206, 208 and dies take place while the leadframes 206, 208 are still integrally connected as a leadframe strip 200. After such processes are completed, the leadframes 206, 208, and sometimes mold compound of the semiconductor package 202, 204, are severed (“singulated” or “diced”) with a cutting tool, such as a saw, laser, or comb tooth punch tool. These singulation cuts separate the leadframe strip 200 into separate integrated circuit (IC) packages, each IC package including a singulated leadframe, at least one die, electrical connections between the die and leadframe 206, 208 (e.g., gold or copper bond wires) and the mold compound which covers at least part of these structures.

Singulating the semiconductor package 202, 204 (step 120) involves making a first cut adjacent to a first side 226, 228 of a first lead 214, 216 of the first plurality of leads 214, 216, the first side extending from the first side 226, 228 of the semiconductor package 202, 204 (step 122). In some examples, the first side of the first lead extends from a side of a semiconductor package toward another package. For example, a cut can be made along a side of a lead that extends from semiconductor package 202 toward semiconductor package 204.

FIG. 2B illustrates cuts to a leadframe 206, 208, according to some examples. Any of the cuts 224a, 224b, 224c, 224d, 224e (collectively, cuts 224) can be considered as the first cut adjacent to the first lead 214, 216 of the first plurality of leads 214, 216. Further, a reference to a singular cut 224 of the cuts 224 can be applied to any of the cuts 224. The semiconductor package can be either semiconductor package 202 or semiconductor package 204, and accordingly, the first lead to be cut can be any of the leads 214 of semiconductor package 202 or leads 216 of semiconductor package 204. Similarly, either side 226, 228 of the lead 214 of semiconductor package 202 or lead 216 of semiconductor package 204 can be cut first. For illustrative purposes, singulating the semiconductor package 202 involves making a cut 224a adjacent to a side 226 of lead 214a of leads 214 of semiconductor package 202. The cut 224a is made along the side 226 of the lead 214a.

By making the cut 224a along the side 226 of the lead 214a, the cut 224 does not pass through the plating at the tip of the lead 214a, and instead, the cut 224a passes through portions of the leadframe strip 200 coupled to the sides 226 of the lead 214. The cut 224a exposes the leadframe material (e.g., copper) of the lead 214 at the side 226 of the lead 214a, instead of the tip of the lead 214a. Further, the cut 224a exposes the leadframe material of the lead 214 where the lead 214 was coupled to other regions of the leadframe 206, 208. For example, the lead 214, as illustrated in FIG. 2A, is coupled to a tie bar 210 at a portion of the side 226 near the tip of the lead 214, and accordingly, the cut 224a exposes a portion of the side 226 of the lead 214 where the tie bar 210 was coupled to the lead 214.

As illustrated, the cut 224a is also made adjacent to openings 222 that help form the tip of the lead 214a. For example, opening 222 has a side that forms the tip of lead 214a, and the cut 224a is made along the side 226 of lead 214a, and along the side of the opening 222. In some examples, the cut 224a is made through a side of the opening 222. In some examples, because a side of the opening 222 forms the tip of the lead 214a, cuts 224 (either cut 224a or cut 224b) can be made along the sides of the opening 222 adjacent to the side that forms the tip of the 214a. In some examples, the cut 224 can pass between two openings 222 into a gap between the leads 214. For example, the leads 214a and 214b each have openings 222 that form their respective tips, and the leads 214a and 214b have a gap between them, that at least partially form the sides of the leads 214a and 214b. Accordingly, in such example, a cut (such as cut 224b) can be made between two openings (i.e., openings that form the tips of the leads 224a and 224b) and into the gap between the two leads 224a and 224b.

In some examples, the cut 224a can be made through any dam bar (e.g., dam bar 218) that couples the lead 214 to other leads of the semiconductor package 202. The cut 224 can also be made through any other metal regions of the leadframe 206, 208 (e.g., tie bars 210, siderails 212).

As illustrated, making a cut 224a adjacent to a side 226 of lead 214a of leads 214 of semiconductor package 202 also involves making the cut 224a adjacent to a side 230 of lead 216a of leads 216 of semiconductor package 204. In some examples, any of the cuts 224 can be made adjacent to respective sides of leads of another semiconductor package. Specifically, as illustrated, cut 224a is made adjacent to side 226 of lead 214a and adjacent to side 230 of lead 216a of semiconductor package 204. In some examples, the cut 224 can have a width equal to the distance between leads 214. Specifically, the width (or thickness) of a cut 224 can be equal to the distance between adjacent sides of adjacent leads.

The first cut can be any of the other cuts 224b, 224c, 224d, 224e. Accordingly, the first cut does not necessarily need to be adjacent to side 226 of lead 214a and side 230 of lead 216a. For example, the first cut can be cut 224b, which will be adjacent to side 228 of lead 214a and to side 232 of lead 216a. Further, the first lead can by any of the other leads 214b, 214c, 214d. Accordingly, the first cut does not need to adjacent to a side of lead 214a or a side of 216a. For example, the first lead can be 214b, and accordingly, the first cut can be cut 224b along respective side 226 of lead 214b or cut 224c along respective side 228 of lead 214b.

In some examples, making the first cut adjacent to a side of a first lead can also involve cutting along the side of another lead. For example, the first cut 224b can be made along the side 228 of lead 214a, which is also along the respective side 226 of lead 214b, accordingly, a single cut can be made adjacent to two different leads. The cuts 224 are perpendicular to the sides of the semiconductor packages 202, 204. Further, the cuts 224 are parallel to the sides 226, 228 of leads 214

Singulating the semiconductor package (step 120) involves making a second cut adjacent to a second side of the first lead of the first plurality of the leads, the second side of the lead opposite the first side of the first lead and extending from the first side of the semiconductor package (step 124). In some examples, the second cut occurs at the same time as the first cut. Any combination of the cuts 224a, 224b, 224c, 224d, 224e can occur simultaneously. For example, a comb tooth punch tool is used for making the cuts 224a, 224b, 224c, 224d, 224e simultaneously. Accordingly, while singulation of the semiconductor package is discussed with regards to the first cut and second cut separately, it is understood that the first cut and the second cut can occur simultaneously, as well as any other cuts required to singulate the semiconductor package.

Any of the cuts 224a, 224b, 224c, 224d, 224e, can be considered as the second cut adjacent to the first lead of the first plurality of leads. Either side of the leads 214 of semiconductor package 202 or leads 216 of semiconductor package 204 can be cut second. For illustrative purposes, singulating the semiconductor package involves making a cut 224b adjacent to a side 228 of lead 214a of leads 214 of semiconductor package 202. As illustrated, the cut 224b is also made adjacent to openings 222 that semiconductor help form the tip of the lead 214a. For example, opening 222 has a side that forms the tip of lead 214a, and the cut 224b is made along the side 228 of lead 214a, and along the side of the opening 222. As cut 224b, for purposes of this illustrative example, is the second cut, cut 224b is made opposite of cut 224a, which was made on the first side 226 on the lead 214a. However, in other examples, any of the other cuts 224a, 224c, 224d, and 224e can be the second cut so long as the first cut is respectively cuts 224b, 224c, 224d, 224e.

Like cut 224a, the cut 224b does not pass through the plating at the tip of the lead 214a, and instead, the cut 224b passes through portions of the leadframe strip 200 coupled to the sides of the lead 214a. The cut 224b exposes the leadframe material (e.g., copper) of the lead 214a at the sides 226, 228, instead of the tip of the lead 214a.

In some examples, the cut 224 can be made through any dam bar (e.g., dam bar 218) that couples the lead 214a to other leads of the semiconductor package 202, 204. The cut 224 can also be made through any other metal regions of the leadframe 206, 208 (e.g., tie bars 210, siderails 212). In some examples, tie bars 210 and siderails 212 may be removed during singulation of the semiconductor packages 202, 204.

In some examples, either cut 224a or cut 224b can also be made along the sides of other leads. For example, cut 224a is also made along the side 230 of lead 216a, and cut 224b is also made along the side 232 of lead 216a. In other examples, cut 224 only cuts along the side 226, 228, 230, 232 of one of the leads 214, 216.

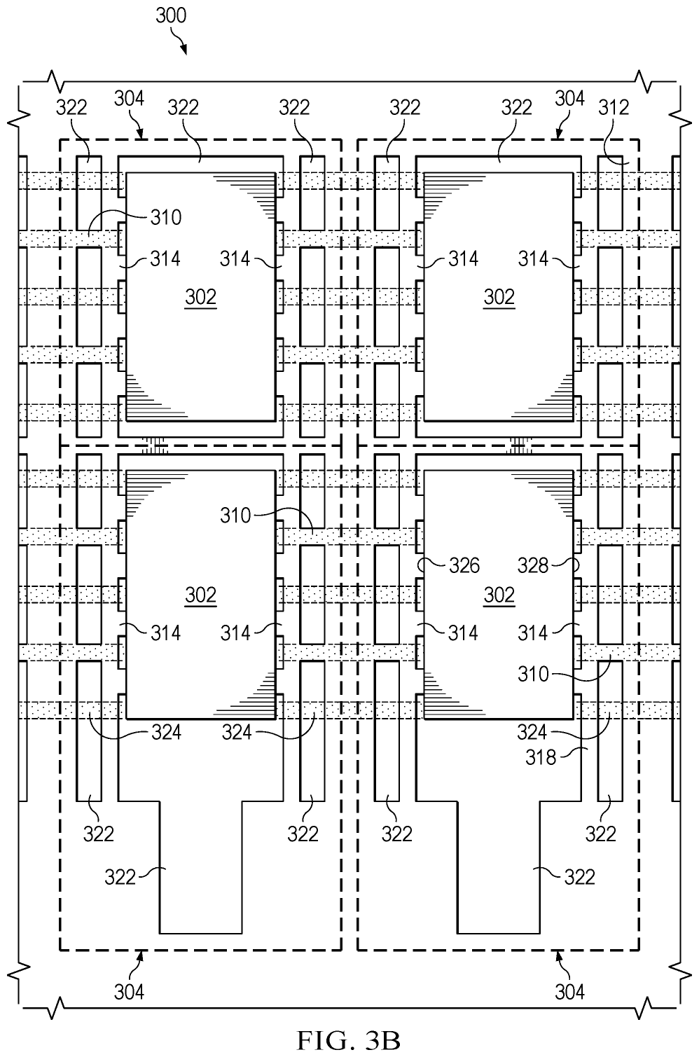

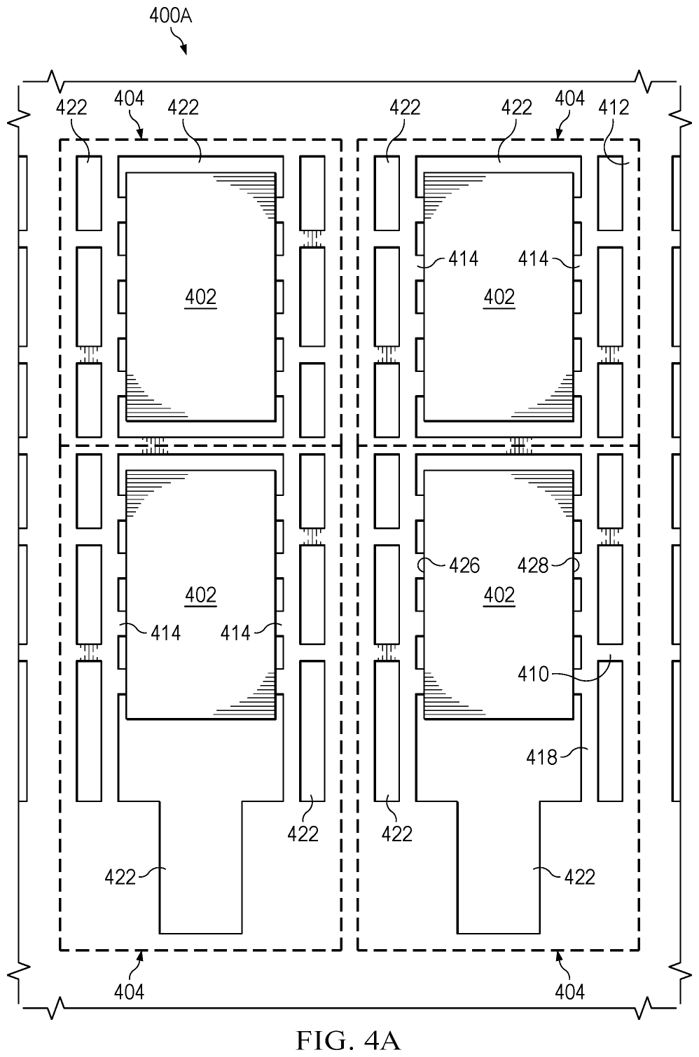

FIG. 3A is a top view of leadframes for semiconductor devices, according to some examples. The leadframe strip 300 of FIG. 3A includes four leadframes 304, for illustrative purposes, but in other examples, the leadframe strip 300 can include any number of leadframes 304 for any number of semiconductor devices. The leadframe strip 300 of FIG. 3A includes leadframes 304 having a different leadframe design as compared to the leadframe design of the leadframes 206, 208 of FIG. 2A. Like the leadframes 206, 208 of FIG. 2A, the leadframes 304 of FIG. 3A have leads 314 extending from sides 326, 328 of each semiconductor package 302. The leadframes 304 of FIG. 3A also include openings 322, like the openings 222 of the leadframes 206, 208 of FIG. 2A. As illustrated, some of the openings 322 of the leadframes 304 are at least partially formed by a side of the semiconductor packages 302. The leadframes 304 also include tie bars 310. The tie bars 310 can separate and delineate openings 322 of the leadframes 304.

FIG. 3B illustrates cuts to leadframes 304 of FIG. 3A, according to some examples. Specifically, the cuts 324 of FIG. 3B singulate the semiconductor packages 302 and leadframes 304 of FIG. 3A. The cuts 324 extend from one side 326 of the semiconductor packages 302 to the other side 328 of an adjacent semiconductor package 302. The cuts 324 can also extend from the sides of the semiconductor packages toward the edges of the leadframe strip 300, and accordingly, the cuts 324 are not necessarily between semiconductor packages 302.

As illustrated, the cuts 324 can pass through openings 322 of the leadframe strip. Any one of the cuts 324 can pass through any number of openings 322. Any one of the cuts 324 can pass through tie bars 310 between openings 322. Any one of the cuts 324 can made into a gap between leads 314. In some examples, cuts 324 can be made that pass through tie bars 310 into a gap between leads 314.

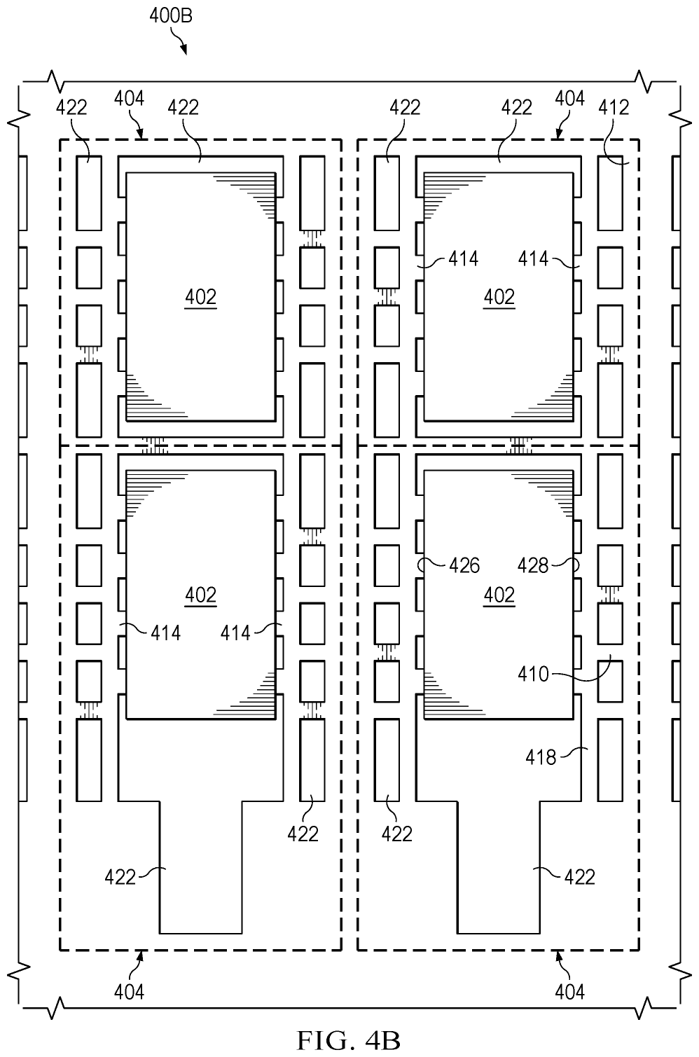

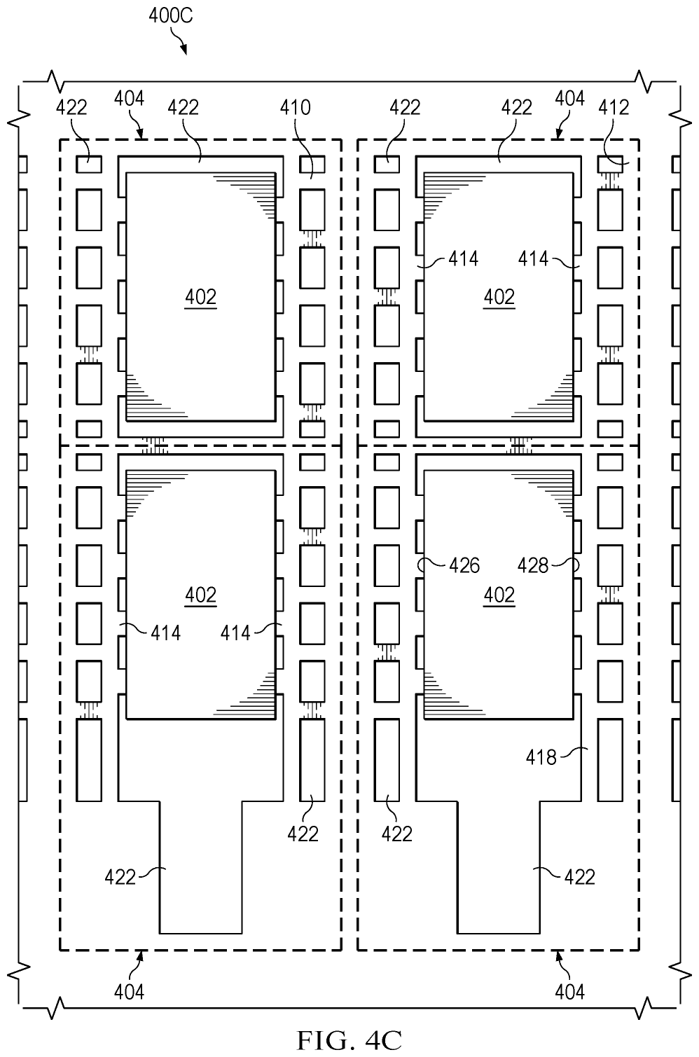

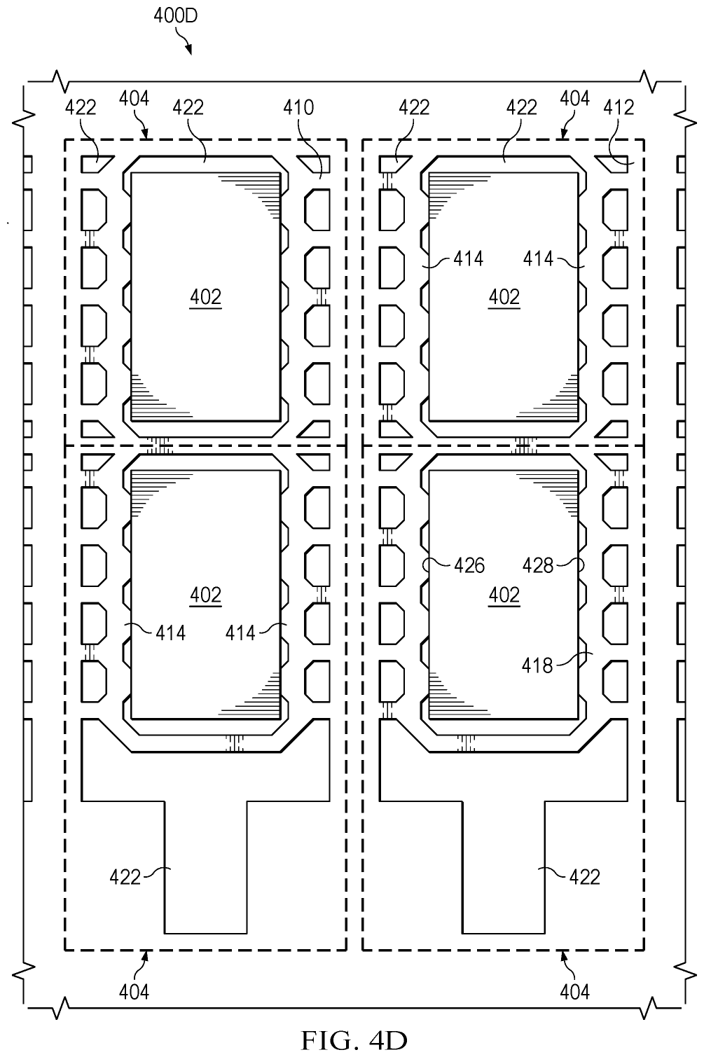

FIG. 4A-4D are top views illustrating leadframes for semiconductor devices, according to some examples. Specifically, the leadframes strips 400A, 400B, 400C, and 400D of FIGS. 4A-4D include dam bars coupling leads of a leadframe. Each of the leadframe strips 400A, 400B, 400C, and 400D include four leadframes 404 with each leadframe having leads 414 connected by a dam bar 418. Like the other leadframes designs described herein, the leadframes 404 of each leadframe strip 400A, 400B, 400C, and 400D includes openings 422. As illustrated in FIG. 4A-4D, the leadframes 404 have different number and different sizes of openings 422. Further, FIG. 4D provides an example of the openings 422 have different shapes as compared to the rectangular shaped openings 422 of FIG. 4A-4B. Specifically, the openings 422 of leadframe 404 of FIG. 4D have hexagonal shapes. In some examples, the openings 422 can have nonlinear sides, i.e., nonlinear from a top view. “Nonlinear from a top view” or plan view with respect of openings in the metal strip of the leadframe means that as one views the metal strip from above the surface one sees that the openings are substantially curvilinear or containing overall non-linear segments.

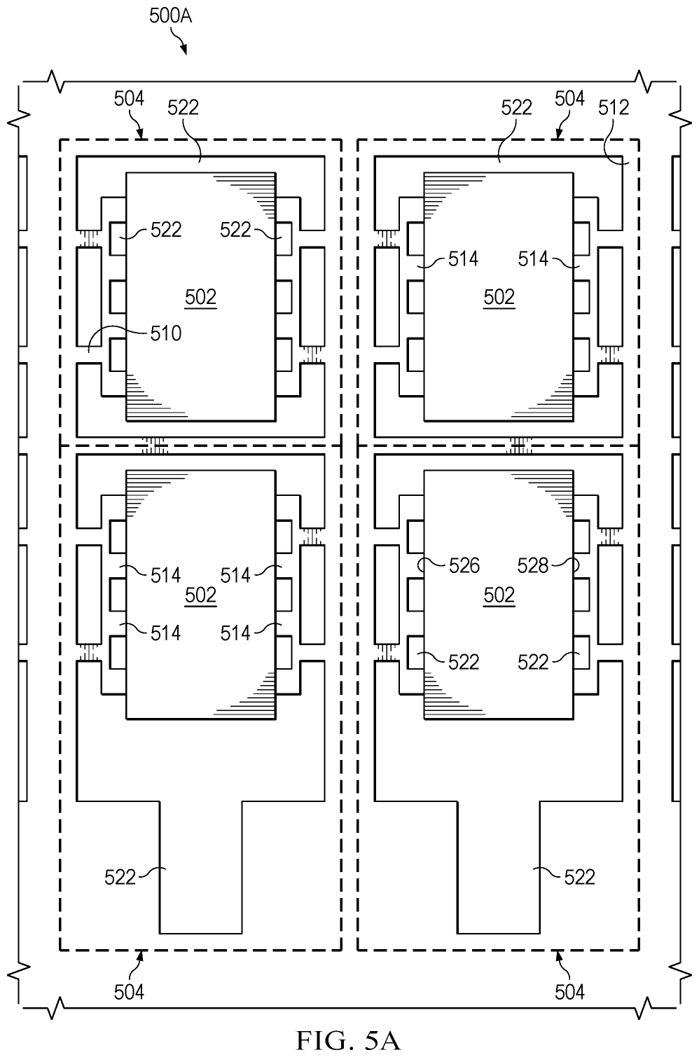

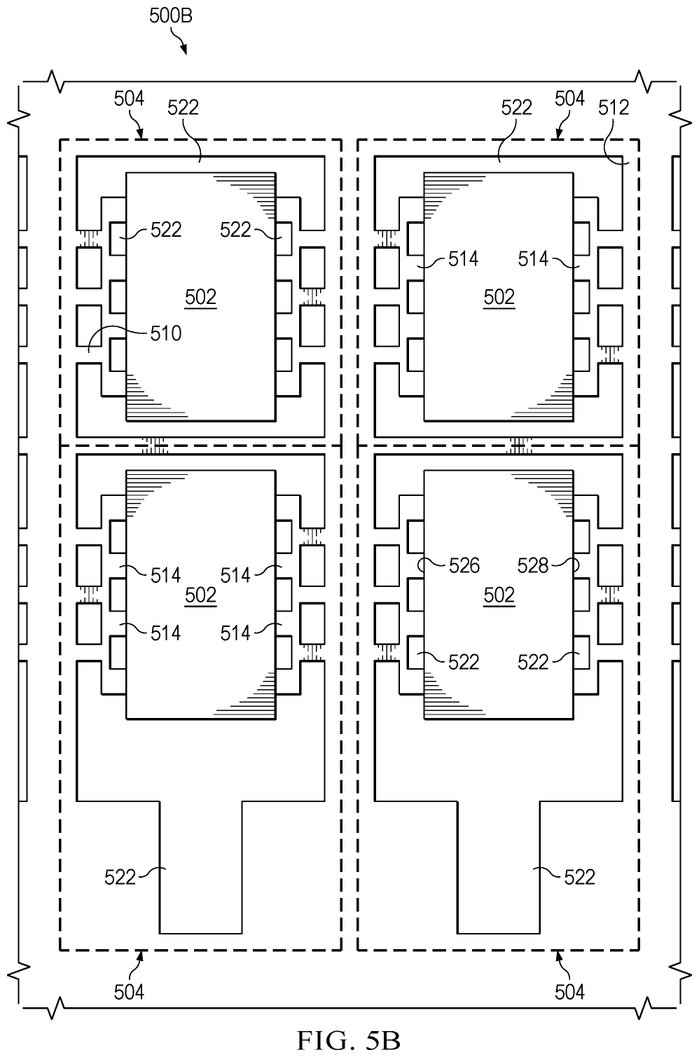

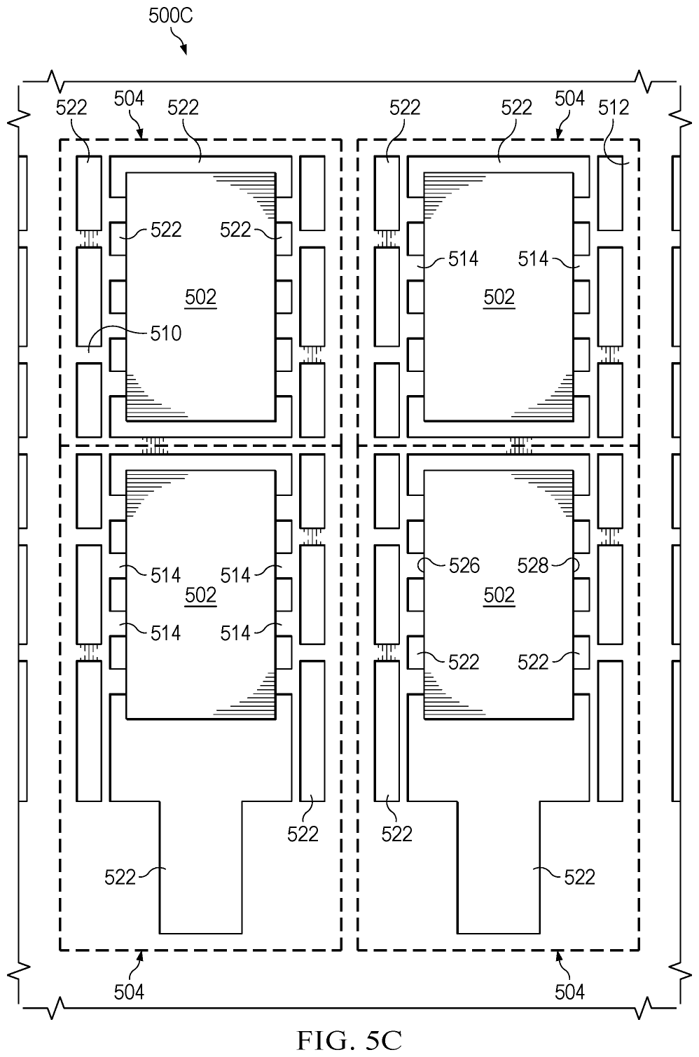

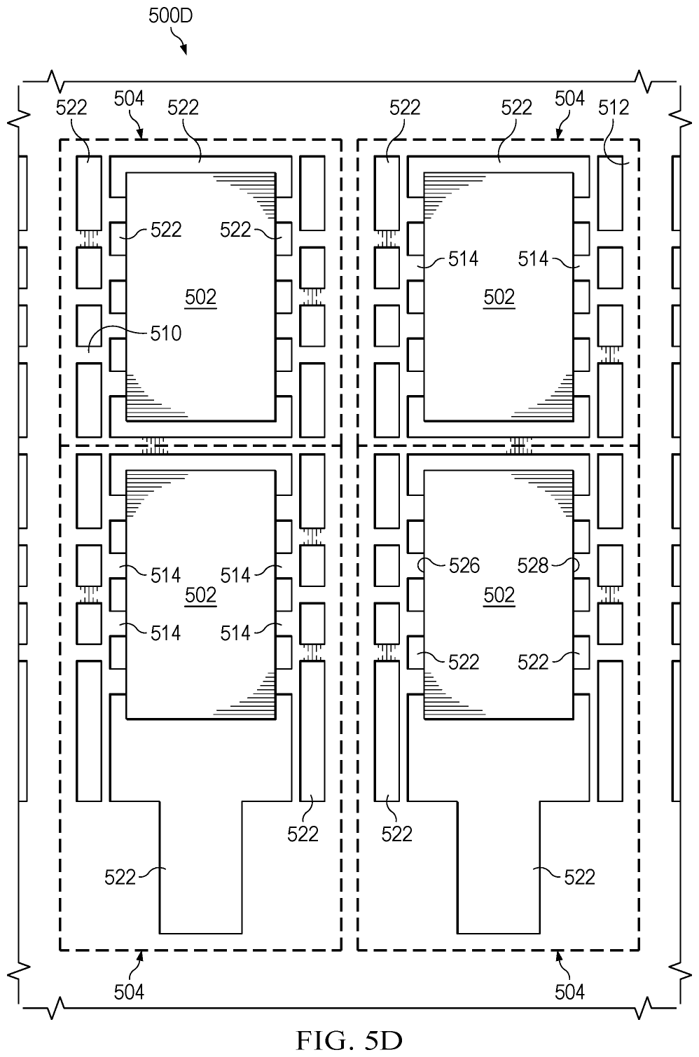

FIG. 5A-5 D are top views illustrating leadframes for semiconductor devices, according to some examples. Specifically, the leadframes strips 500A, 500B, 500C, and 500D of FIGS. 5A-5D lack dam bars that would have otherwise coupled leads of a leadframe. Like leadframes 404 of FIGS. 4A-4D, each of the leadframe strips 500A, 500B, 500C, and 500D include four leadframes 504 with each leadframe having leads 514. Like the other leadframes designs described herein, the leadframes 504 of each leadframe strip 500A, 500B, 500C, and 500D includes openings 522. As illustrated in FIG. 5A-5D, the leadframes 504 have different number and different sizes of openings 522. Further, FIG. 4D provides an example of the openings 522 have different shapes as compared to the rectangular shaped openings 522 of FIG. 4A-4B. Specifically, the openings 522 of leadframe 504 of FIG. 4D have hexagonal shapes. In some examples, the openings 522 can have nonlinear sides.

The leadframe strips 400A, 400B, 400C, and 400D of FIGS. 4A-4D and the leadframe strips 500A, 500B, 500C, and 500D of FIGS. 5A-5D have leadframes 404 and 504 of different leadframe designs. Each of the leadframe strips of FIGS. 4A-4D and FIGS. 5A-5D can be cut according to the methods described here. The cuts described with reference to FIGS. 2A-2B and FIGS. 3A-3B can be applied to any of the leadframe strips of FIGS. 4A-4D and FIGS. 5A-5D.

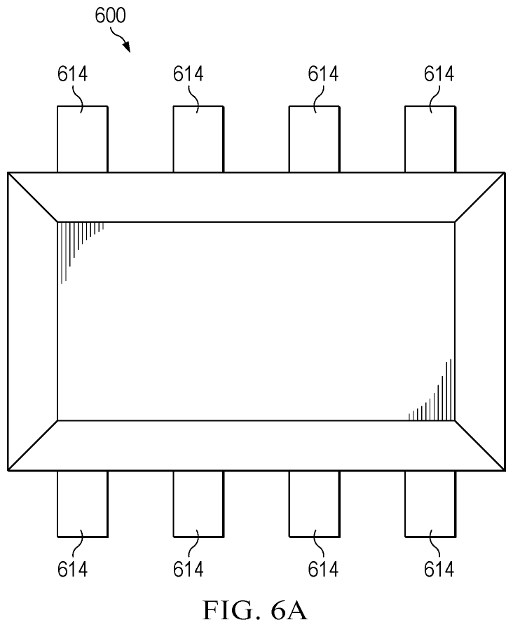

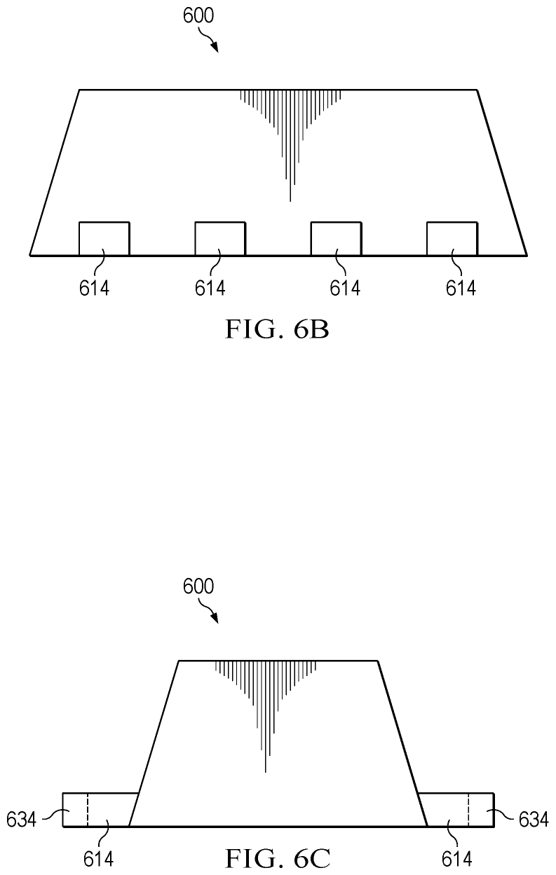

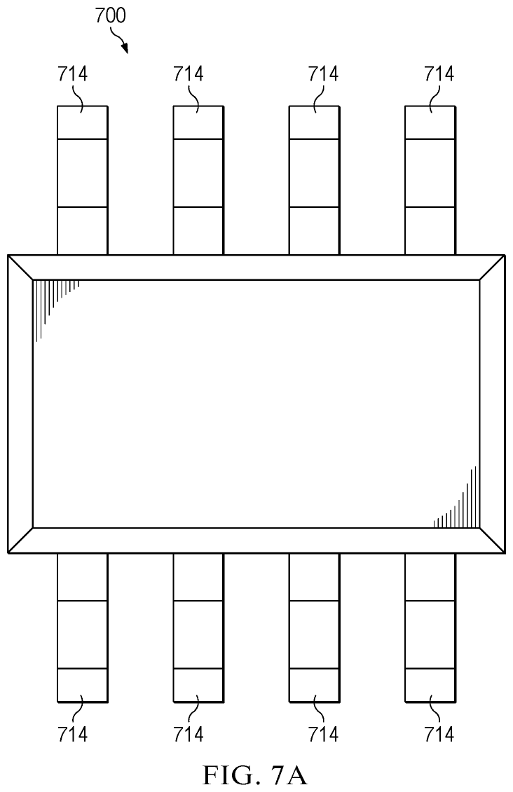

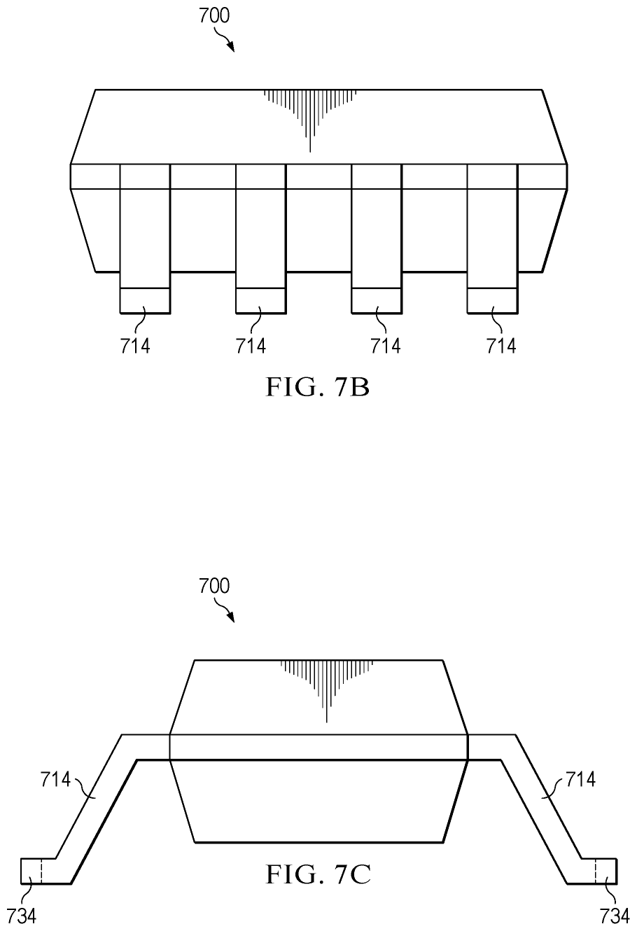

FIGS. 6A-6C are different views of a singulated semiconductor device, and FIGS. 7A-7C are different views of a singulated semiconductor device, according to some examples. Specifically, FIGS. 6A-6C illustrate a flat lead package 600 singulated as described herein, and FIGS. 7A-7C illustrate a gullwing lead package 700 singulated as described herein.

In FIGS. 6A-6C, the flat lead package 600 has leads 614 cut as described herein. Accordingly, as illustrated in FIG. 6B, the tips of the leads 614 are still plated after singulation except for the portions 634 of the sides of the leads 614, where the leads 614 were cut from the rest of a leadframe, as illustrated in FIG. 6C.

In FIGS. 7A-7C, the gullwing package 700 has leads 714 cut as described herein. Accordingly, as illustrated in FIG. 7B, the tips of the leads 714 are still plated after singulation except for the portions 734 of the sides of the leads 714, where the leads 714 were cut from the rest of a leadframe, as illustrated in FIG. 7C.

The various examples disclosed herein provide benefits in addition to the advantages described above. For instance, the differing leadframes described above enable singulation of semiconductor packages with plated lead tips. Such benefits, in turn, may provide other benefits; for example, the plated lead tips enable stable solder fillets during the SMT process. The various examples disclosed may provide additional advantages that are not expressly described herein.

In the foregoing discussion and in the claims, the terms “including” and “comprising” are used in an open-ended fashion, and thus should be interpreted to mean “including, but not limited to . . . ” Also, the term “couple” or “couples” is intended to mean either an indirect or direct connection. Thus, if a first device couples to a second device, that connection may be through a direct connection or through an indirect connection via other devices and connections. Similarly, a device that is coupled between a first component or location and a second component or location may be through a direct connection or through an indirect connection via other devices and connections. An element or feature that is “configured to” perform a task or function may be configured (e.g., programmed or structurally designed) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof. Additionally, uses of the phrases “ground” or similar in the foregoing discussion are intended to include a chassis ground, an Earth ground, a floating ground, a virtual ground, a digital ground, a common ground, and/or any other form of ground connection applicable to, or suitable for, the teachings of the present disclosure. Unless otherwise stated, “about,” “approximately,” or “substantially” preceding a value means+/−10 percent of the stated value.

The above discussion is meant to be illustrative of the principles and various embodiments of the present disclosure. Numerous variations and modifications will become apparent to those skilled in the art once the above disclosure is fully appreciated. It is intended that the following claims be interpreted to embrace all such variations and modifications.

What is claimed is:

1. A method of forming a semiconductor package, the method comprising:
forming the semiconductor package having a first plurality of leads extending from a first side of the semiconductor package, the semiconductor package disposed on a leadframe, the leadframe comprising the first plurality of leads, wherein each of the first plurality of leads comprises leadframe material and plating;
making a first cut adjacent to a first side of a first lead of the first plurality of leads, the first side extending from the first side of the semiconductor package; and
making a second cut adjacent to a second side of the first lead of the first plurality of the lead, the second side of the lead opposite the first side of the lead and extending from the first side of the semiconductor package.

2. The method of claim 1, wherein making the first cut comprises exposing a portion of the leadframe material of the first lead.

3. The method of claim 1, wherein making the first cut comprises making the first cut adjacent to a third side of a second lead of the first plurality of leads, the third side extending from the first side of the semiconductor package.

4. The method of claim 3, wherein making the first cut adjacent to the third side of the second lead exposes a portion of leadframe material of the second lead.

5. The method of claim 1, wherein making the first cut comprises making the first cut parallel to the first side of the first lead.

6. The method of claim 1, wherein making the first cut comprises making the first cut through a dam bar coupled to the first plurality of leads.

7. The method of claim 1, wherein the semiconductor package comprises a flat lead package.

8. The method of claim 1, wherein the semiconductor package comprises a gullwing lead package.

9. The method of claim 1, wherein the first lead comprises a first lead tip disposed between the first side of the first lead and the second side of the first lead, and the first lead tip is plated.

10. The method of claim 1, wherein a portion of a side of a lead of the first plurality of leads is exposed.

11. The method of claim 1, wherein the leadframe comprises a plurality of openings disposed adjacent to the first lead.

12. The method of claim 11, wherein making the first cut comprises making the first cut through a first side of a first opening of the plurality of openings, the first opening having the first side and a second side opposite the first side.

13. The method of claim 11, wherein making the first cut comprises making the first cut along a first side of a first opening of the plurality of openings, the first side disposed between a second side and a third side opposite the second side, the second side of the opening forming a lead tip of the first lead.

14. The method of claim 11, wherein making the first cut comprises making the first cut through the leadframe between two openings of the plurality of openings into a gap between the first lead and a second lead.

15. The method of claim 1, wherein a width of the first cut is equal to a distance between the first side of the first lead and a first side of a second lead.

16. A method for manufacturing a semiconductor device, the method comprising:
forming a leadframe strip comprising a first package and a second package, the first package having a first plurality of leads extending from a first side of the first package towards the second package, the second package having a second plurality of leads extending from a second side of the second package toward the first package, the first package and the second package disposed adjacent to each other on the leadframe strip, wherein each of the first plurality of leads comprises leadframe material and plating;
making a first cut adjacent to a first side of a first lead of the first plurality of leads, the first side extending from the first side of the first package toward the second package; and
making a second cut adjacent to a second side of the first lead of the first plurality of the lead, the second side of the lead opposite the first side of the lead and extending from the first side of the first package toward the second package.

17. The method of claim 16, wherein making the first cut comprises making the first cut adjacent to a first side of a second lead of the second plurality of leads, the first side of the second lead extending from the second side of the second package toward the first package.

18. The method of claim 16, wherein making the second cut comprising making the second cut adjacent to a second side of a second lead of the second plurality of leads, the second side of the second lead opposite of a first side of the second lead, the second side of the second lead extending from the second side of the second package toward the first package.

19. The method of claim 16, wherein making the first cut comprising cutting through a first dam bar of the leadframe strip, the first dam bar coupling the first plurality of leads.

20. A semiconductor device, comprising:
a first plurality of leads extending from a first side of a package, each of the first plurality of leads including a lead material and a plating on the lead material;
a first lead of the first plurality of leads having:
a first portion of the lead material exposed on a first end of a first side extending from the first side of the package;
a second portion of the lead material exposed a first end of a second side extending from the first side of the package, the second side opposite the first side; and
full plating coverage on a third side, a fourth side, and a fifth side of the package, the third side between the first and second sides and extending from the first side of the package, the fourth side between the first and second sides and extending from the first side of the package, and the fifth side being adjacent to the first side, the second side, the third side, and the fourth side.
